(19) United States
(12) Patent Application Publication
(10) Pub. No.: US 2014/0117474 A1
(43) Pub. Date: May 1, 2014

(54) PRESSURE SENSING DEVICE AND MANUFACTURING METHOD OF THE SAME

(71) Applicant: DENSO CORPORATION, Kariya-city (JP)

(72) Inventor: Makoto Sakai, Kariya-city (JP)

(73) Assignee: DENSO CORPORATION, Kariya-city (JP)

(21) Appl. No.: 14/059,890

(22) Filed: Oct. 22, 2013

(30) Foreign Application Priority Data
Oct. 26, 2012 (JP) 2012-236601

(51) Int. Cl. B81B 7/00; B81C 1/00

(52) U.S. Cl. CPC B81B 7/0058; B81C 1/00333
USPC 257/417; 438/51

(57) ABSTRACT

A pressure sensing device includes a sensor chip having a sensing portion, a bonding wire, a protection section, a package, and a guide member. The sensor chip detects a pressure with the sensing portion and generates a signal corresponding to the pressure. The bonding wire is electrically connected with the sensor chip in order to transmit the signal generated by the sensor chip. The protection section has an electrical insulation property and seals the sensor chip and the bonding wire. The package houses the sensor chip, the bonding wire, and the protection section. The guide member has a tubular section arranged opposed to the sensing portion. The protection section has a first thickness at an inside portion of the tubular section and has a second thickness, which is larger than the first thickness, at an outside portion of the tubular section.

### CROSS REFERENCE TO RELATED APPLICATION

This application is based on Japanese Patent Application No. 2012-236601 filed on Oct. 26, 2012, the disclosure of which is incorporated herein by reference.

### TECHNICAL FIELD The present disclosure relates to a pressure sensing device including a sensor chip, a bonding wire, a protection section and a package, and a manufacturing method of the same.

### BACKGROUND

As disclosed in JP 3858577 B2 (corresponding to US 2001/0028072 A1), a technology related to a semiconductor pressure sensing device that restricts a generation of a void caused by chemicals and moisture existing in the environment in a protection section is disclosed. The semiconductor pressure sensing device includes a conductive portion, a sensor chip, bonding wires, and a protection section. The protection section is made of a material, which has a saturated swelling coefficient of 7 weight percent at most when the material is immersed into gasoline having a temperature of 20 Celsius degrees.

According to the technology disclosed in JP 3858577 B2, the protection section needs to be formed thickly in order to protect the sensor chip and the bonding wires. When the pressure sensing device having a thickly formed protection section is used to detect a collision, the sensor chip receives an effect of an impact acceleration caused by an external reason and the sensor chip may perform a false detection.

In order to reduce the effect caused by the impact acceleration, the protection section needs to be formed thinly. On the other hand, when the protection section is thinly formed, a reliability of the pressure sensing device may be reduced caused by an exposure of the bonding wires and the like.

### SUMMARY

In view of the foregoing difficulties, it is an object of the present disclosure to provide a pressure sensing device, which reduces an effect caused by an impact acceleration and secures a reliability of bonding wires, and a manufacturing method of the pressure sensing device.

According to a first aspect of the present disclosure, a pressure sensing device includes a sensor chip having a sensing portion, a bonding wire, a protection section, a package, and a guide member. The sensor chip detects a pressure with the sensing portion, and generates a signal corresponding to the pressure detected by the sensing portion. The bonding wire is electrically connected with the sensor chip in order to transmit the signal generated by the sensor chip. The protection section has an electrical insulation property and seals the sensor chip and the bonding wire. The package houses the sensor chip, the bonding wire, and the protection section. The guide member has a tubular section arranged opposed to the sensing portion of the sensor chip. The protection section has a first thickness at an inside portion of the tubular section, and has a second thickness at an outside portion of the tubular section. The first thickness is smaller than the second thickness.

With the above device, an effect caused by an impact acceleration is reduced and a reliability of the bonding wire is secured.

According to a second aspect of the present disclosure, a manufacturing method of the pressure sensing device according to the first aspect includes arranging the guide member having the tubular section so that the tubular section is opposed to the sensing portion and an end surface of the tubular section is spaced from a surface of the sensing portion by a gap, and sealing the sensor chip and the bonding wire with the protection section by providing a material of the protection section from the outside portion of the tubular section.

With the above method, an effect caused by an impact acceleration is reduced and a reliability of the bonding wire is secured.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram showing a cross-sectional view of a pressure sensing device according to an embodiment of the present disclosure;

FIG. 2 is a diagram showing a cross-sectional view of the pressure sensing device during a position defining process;

FIG. 3 is a diagram showing a top view of a guide member of the pressure sensing device;

FIG. 4 is a diagram showing a cross-sectional view of the pressure sensing device after a position of the guide member is defined;

FIG. 5 is a diagram showing a cross-sectional view of the pressure sensing device during a cap attaching process;

FIG. 6 is a diagram showing a cross-sectional view of the pressuring sensing device during a sealing process;

FIG. 7 is a diagram showing a cross-sectional view of the pressure sensing device during a cap removing process; and

FIG. 8 is a diagram showing an example in which the pressure sensing device is equipped to a vehicle.

### DETAILED DESCRIPTION

The following will describe embodiments of the present disclosure with reference to the drawings. In the present disclosure, the words “connect, connection” mean “electrically connect, electrical connection”. Similarly, the words “insulate, insulation” mean “electrically insulate, electrical insulation”. Each of the drawings illustrates elements necessary to describe a configuration of a pressure sensing device 10 according to the present disclosure instead of illustrating all of the elements.

### First Embodiment

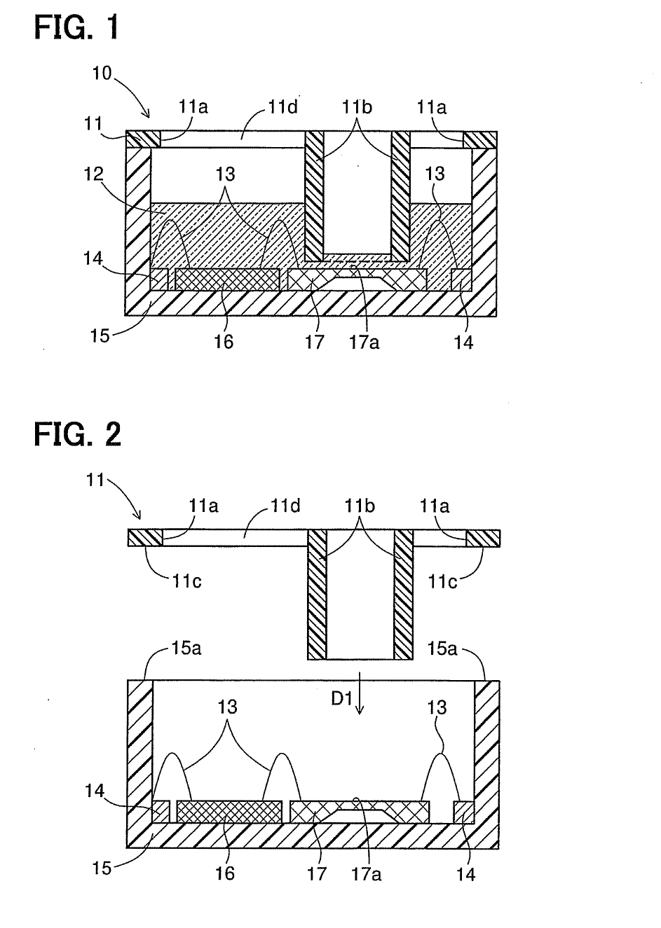

The following will describe the pressure sensing device 10 according to a first embodiment of the present disclosure with reference to FIG. 1 to FIG. 8. As shown in FIG. 1, the pressure sensing device 10 includes a guide member 11, a protection section 12, bonding wires 13, leads 14, a package 15, a circuit chip 16, and a sensor chip 17. The circuit chip 16 includes an integrated circuit, and the leads 14 include lead frames.

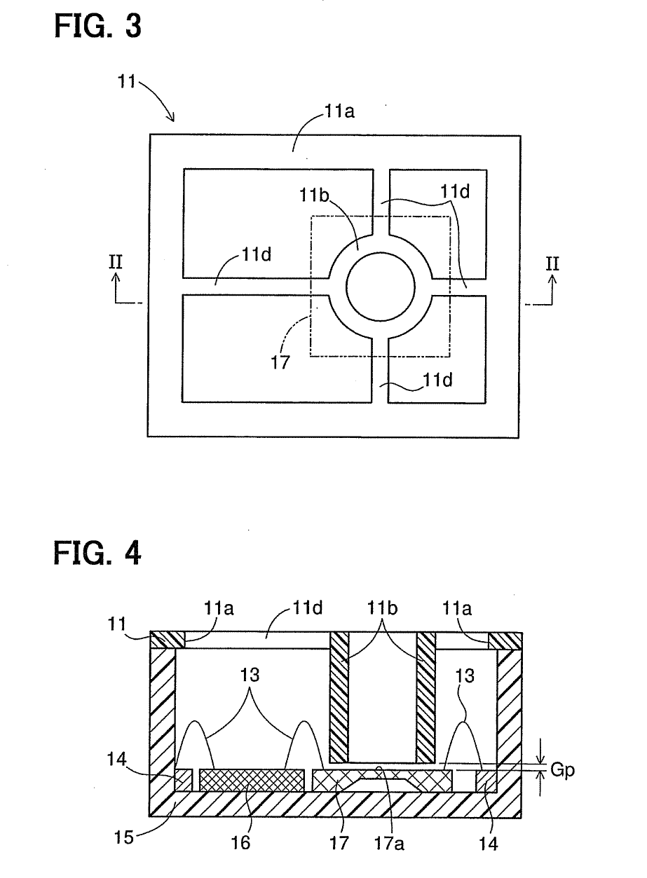

As shown in FIG. 2 and FIG. 3, the guide member 11 includes a positioning section 11a, a tubular section 11b, and a support section 11d. The positioning section 11a defines a position of the guide member 11 at a predetermined portion of the package 15. In the present embodiment, as shown in FIG. 2, an end part 11c of the positioning section 11a is contacted with an end part 15a of the package 15 so that the guide member 11 is arranged at the predetermined portion of the package 15. The end part 11c of the positioning section 11a may be contacted with the end part 15a of the package 15 by a surface, a point, or a line. That is, the positioning section 11a is shaped to fit with a shape of the end part 15a of the package 15. The tubular section 11b is formed so that the tubular section 11b is opposed to a sensing portion 17a of the sensor chip 17 when the position of the guide member 11 is defined by the positioning section 11a. As shown in FIG. 2 and FIG. 3, in the present embodiment, the tubular section 11b is shaped to have a cylindrical shape. Further, the tubular section 11b may have a different tube-shape under a condition that the sensing portion 17a of the sensor chip 17 is arranged opposed to an inside portion of the tubular section 11b. The support section 11d supports the tubular section 11b so that the tubular section 11b is arranged at a predetermined position opposed to the sensing portion 17a of the sensor chip 17.

The protection section 12 seals the components and the elements arranged in the package 15. Specifically, the protection section 12 seals the bonding wires 13, the leads 14, the circuit chip 16, and the sensor chip 17. The protection section 12 is made of insulating gel material, which is gelatinized under a heating treatment. Herein, the gelatinization includes solidification, and the gel material includes resin material. In the present embodiment, the protection section 12 is made of silicon gel. Further, the protection section 12 may be made of fluorine gel.

The bonding wires 13 are conducting wires that transmit output signals of the sensor chip 17 to the leads 14 or to the circuit chip 16. The leads 14 are provided by conductors, which are used for terminals that transmit signals and information to internal wires of the pressure sensing device 10 and transmit signals and information output from the pressure sensing device 10 to an external device or circuit. The circuit chip 16 receives output signals of the sensor chip 17 and performs a necessary process, such as an analog to digital conversion.

The package 15 houses the bonding wires 13, the protection section 12, the leads 14, the circuit chip 16, and the sensor chip 17. The package 15 may have any shape and configuration, and may be made of any material under a condition that the package 15 is able to house the bonding wires 13, the protection section 12, the leads 14, the circuit chip 16, the sensor chip 17 and the like. In the present embodiment, the package 15 is made of resin material and has a box shape with one opening on a surface.

In the present embodiment, the sensor chip 17 includes a pressure sensor that corresponds to the sensing portion 17a. The pressure sensor detects a pressure, particularly an air pressure. The pressure sensor may be provided by any sensor that is able to detect a pressure, particularly an air pressure. For example, a piezo-resistive pressure sensor may be provided as the pressure sensor of the sensor chip 17. The sensor chip 17 generates and outputs a signal that changes with the air pressure detected by the pressure sensor.

The following will describe a manufacturing method of the above-described pressure sensing device 10 with reference to FIG. 2 to FIG. 7. The manufacturing method includes a position defining process, a cap attaching process, a sealing process, and a cap removing process. The cap attaching process and the cap removing process are also referred to as a cap attaching-removing process. An execution order of the position defining process and the cap attaching process may be switched. The following will describe each manufacturing process of the manufacturing method of the pressure sensing device 10. In the present embodiment, suppose that the leads 14, the circuit chip 16, and the sensor chip 17 are properly arranged in the package 15 and the connection points are connected by the bonding wires 13 before carrying out the manufacturing processes.

(Position Defining Process)

In the position defining process, the guide member 11 is arranged on the package 15. Specifically, as shown in FIG. 2 by an arrow D1, the guide member 11 is moved in an approaching direction toward the package 15, and arranged on the package 15 by contacting the end part 11c of the positioning section 11a with the end part 15a of the package 15. Further, the guide member 11 may be fixed to the package 15 after arranging the guide member 11 on the package 15.

In the present embodiment, the guide member 11, which includes the positioning section 11a, the tubular section 11b, and the support section 11d, has a shape shown in FIG. 2 and FIG. 3. The positioning section 11a is shaped to fit with the end part 15a of the package 15, which is arranged adjacent to the opening of the package 15. The tubular section 11b may have any tube shape. In the present embodiment, the tubular section 11b has a cylindrical shape. The support section 11d supports the tubular section 11b so that the tubular section 11b is arranged opposed to the sensor chip 17, particularly opposed to the sensing portion 17a of the sensor chip 17. In the present embodiment, as shown in FIG. 3, the support section 11d has four sub sections to support the tubular section 11b. However, the number of the sub sections of the support section 11d and the shape of the support section 11d are not limited to the support section 11d shown in FIG. 3.

FIG. 4 shows a state after the position of the guide member 11 is defined with respect to the package 15. As shown in FIG. 4, an end surface of the guide member 11 is spaced from a surface of the sensor chip 17 by a gap Gp. More specifically, the end surface of the tubular section 11b of the guide member 11 is spaced from the surface of the sensing portion 17a of the sensor chip 17 by a gap Gp. The material of the protection section 12, which will be described later, flows from an outside portion of the tubular section 11b to the inside portion of the tubular section 11b through the gap Gp.

(Cap Attaching Process)

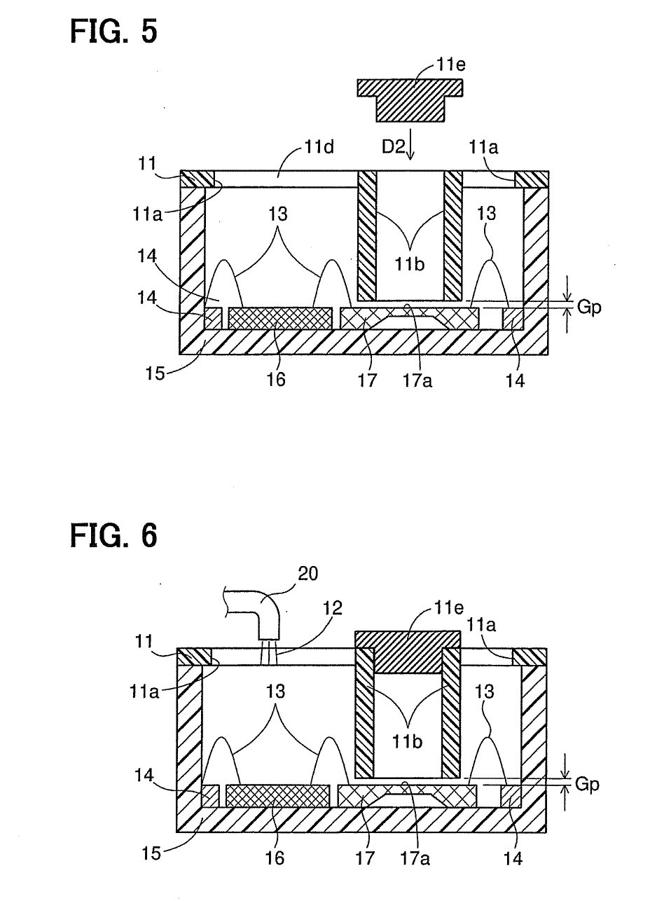

In the cap attaching process, as shown in FIG. 5 by an arrow D2, a cap 11e is moved toward the tubular section 11b, and is attached to one end of the tubular section 11b in order to air-tightly seal the tubular section 11b. The cap attaching process may be carried out together with the position defining process concurrently. Further, the cap attaching process may be carried out before or after the position defining process. The cap 11e attached to the tubular section 11b adjusts a thickness of the material of the protection section 12 filled into the inside portion of the tubular section 11b. FIG. 6 shows a state after the cap 11e is attached to the tubular section 11b.

(Sealing Process)

In the sealing process, the sensor chip 17, the bonding wires 13 and other components and elements are sealed by the protection section 12. Specifically, as shown in FIG. 6, an inside portion of the package 15 is filled with the fluid material of the protection section 12. The fluid material, of the protection section 12 is provided by a providing apparatus 20. Since the material of the protection section 12 has the fluid state, the material of the protection section 12 moves in the package 15 from the outside portion of the tubular section 11b to the inside portion of the tubular section 11b and seals the components and elements arranged in the package 15. A thickness of the material of the protection section 12, which is filled into the package 15, changes corresponding to an amount of the filled material of the protection section 12. The material of the protection section 12 also flows to the inside portion of the tubular section 11b. However, in the present embodiment, the thickness of the protection section 12 at the inside portion of the tubular section 11b is different from the thickness of the protection section 12 at the outside portion of the tubular section 11b. Hereinafter, the thickness of the protection section 12 at the inside portion of the tubular section 11b is also referred to as a first thickness, and the thickness of the protection section 12 at the outside portion of the tubular section 11b is also referred to as a second thickness. The material of the protection section 12 flows to the inside portion of the tubular section 11b through a space at the other end of the tubular section 11b under a condition that the cap 11e is attached at one end of the tubular section 11b. Herein, the space at the other end of the tubular section 11b corresponds to the gap Gp between the sensing portion 17a of the sensor chip 17 and the tubular section 11b of the guide member 11. Since the one end of the tubular section 11b is air-tightly sealed by the cap 11e, an air pressure at the inside portion of the tubular section 11b changes corresponding to the amount of the material of the protection section 12 that flows to the inside portion of the tubular section 11b. The air pressure in the tubular section 11b stops changing when a pressure generated by a movement of the material of the protection section 12 is equal to the air pressure in the tubular section 11b. Thus, the thickness of the material of the protection section 12 in the tubular section 11b can be adjusted to a predetermined thickness Th by changing a length H of the tubular section 11b. That is, the thickness of the protection section 12 to be sealed on the sensor chip 17 can be adjusted to the predetermined thickness Th by changing the length H of the tubular section 11b. The material of the protection section 12 is filled into the package 15 so that the bonding wires 13 are entirely sealed by the protection section 12 and is not exposed to an outside. Then, a heating treatment is performed to the material of the protection section 12 so that the material of the protection section 12 changes from the fluid state to a gel state. The protection section 12 changes from the fluid state to the gel state when being heated for a predetermined time. The predetermined time changes with the amount of the material of the protection section 12 and a temperature of the heating treatment.

(Cap Removing Process)

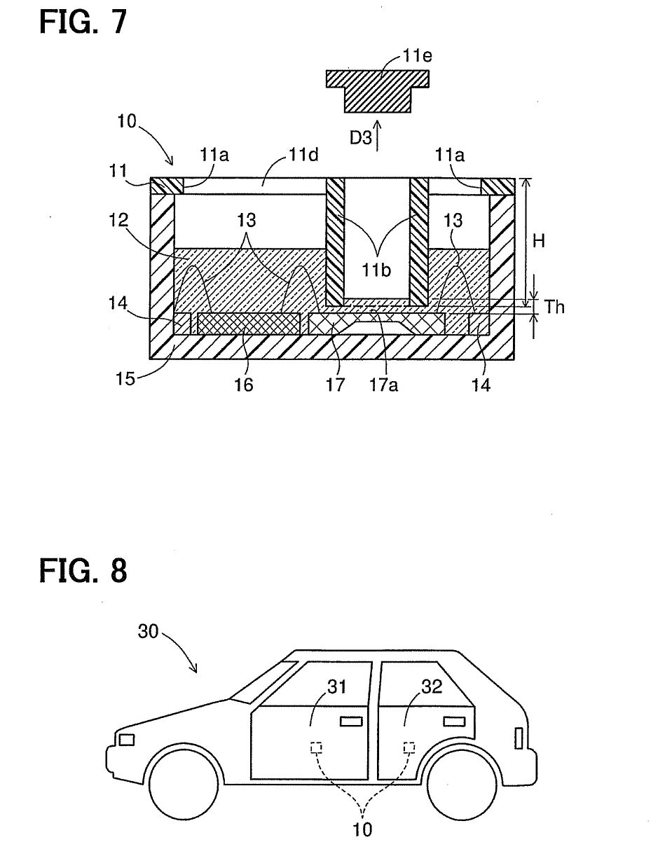

In the cap removing process, the cap 11e is removed from the tubular section 11b after the material of the protection section 12 changes from the fluid state to the gel state. The sensor chip 17 cannot detect a pressure with the cap 11e attached to the one end of the tubular section 11b. Thus, as shown in FIG. 7 by an arrow D3, the cap 11e is removed from the tubular section 11b in a direction apart from the tubular section 11b. FIG. 1 shows the pressure sensing device 10 after the cap 11e is removed from the tubular section 11b.

The following will describe an example in which the above-described pressure sensing device 10 is mounted to a target with reference to FIG. 8. As shown in FIG. 8, the pressure sensing device 10 is arranged at an inside portion of each door 31, 32 of a vehicle 30. With this configuration, when a collision occurs to a side portion of the vehicle. 30 and the collision causes a deformation of the door 31, 32, the pressure sensing device 10, specifically the sensor chip 17 detects a change of the air pressure caused by the deformation of the door 31, 32 in order to determine whether to activate a side airbag or a curtain shield airbag of the vehicle 30. Further, except the doors 31, 32 of the vehicle 30, the pressure sensing device 10 may be mounted to a portion of the vehicle 30 at where the air pressure changes in response to the collision.

As shown in FIG. 7, in the pressure sensing device 10 according to the present embodiment, the protection section 12 sealed on the sensing portion 17a of the sensor chip 17 has the predetermined thickness Th. Further, the predetermined thickness Th of the protection section 12 at the inside portion of the tubular section 11b is smaller than the thickness of the protection section 12 at the outside portion of the tubular section 11b. When the collision occurs to the door 31, 32 of the vehicle 30 by any reason, the sensor chip 17 corresponding to the door 31, 32 detects a pressure change caused by an impact received at the door 31, 32. The sensing portion 17a of the sensor chip 17 is subject to an impact acceleration caused by the collision occurred to the door 31, 32 of the vehicle 30. The impact acceleration applied to the sensing portion 17a is defined by a mass of the protection section 12, which is sealed on the sensing portion 17a and has the predetermined thickness Th. Since the protection section 12 sealed on the sensing portion 17a has the thickness smaller than the thickness of the protection section 12 at the outside portion of the tubular section 11b, an effect of the impact acceleration is reduced at the sensing portion 17a. Thus, when the sensing portion 17a detects the pressure change, an abnormal effect of the impact acceleration applied to the sensing portion 17a is reduced. Since the pressure sensing device 10 detects the pressure change of the air inside of the door 31, 32, each door 31, 32 needs only one pressure sensing device 10 to detect the pressure change.

In the present embodiment, the thickness of the protection section 12 sealed on the components and elements other than the sensing portion 17a of the sensor chip 17 is larger than the thickness of the protection section 12 sealed on the sensing portion 17a. Specifically, the bonding wires 13 are securely sealed by the protection section 12 so that the bonding wires 13 are not exposed to an outside. Thus, a fault caused by an exposure of the bonding wires 13 is restricted, and accordingly, a reliability of the pressure sensing device 10 is secured.

The following will describe advantages provided by the pressure sensing device 10 according to the present embodiment.

(I) In the present embodiment, as shown in FIG. 1, the pressure sensing device 10 includes the guide member 11, which has the tubular section 11b arranged opposed to the sensing portion 17a of the sensor chip 17. Further, the thickness of the protection section 12 at the inside portion of the tubular section 11b is smaller than the thickness of the protection section 12 at the outside portion of the tubular section 11b. Thus, the thickness of the protection section 12 sealed on the sensor chip 17 is smaller than the thickness of the protection section 12 sealed on other components and elements arranged in the package 15. Thus, the effect of the impact acceleration is reduced at the sensing portion 17a, and a false detection of the sensor chip 17 is substantially restricted. Further, the bonding wires 13 are entirely sealed by the protection section 12 so that the bonding wires 13 are not exposed to an outside. Thus, a fault caused by an exposure of the bonding wires 13 is restricted and a reliability of the pressure sensing device 10 is secured.

(II) In the present embodiment, as shown in FIG. 7, the thickness of the protection section 12 at the inside portion of the tubular section 11b is adjustable by changing the length H of the tubular section 11b. With this configuration, the thickness of the protection section 12 sealed on the sensor chip 17 can be adjusted by changing the length H of the tubular section 11b. Thus, the protection section 12 sealed on the sensor chip 17 can be adjusted to have the predetermined thickness Th.

(III) In the present embodiment, the guide member 11 includes the positioning section 11a that is arranged at the predetermined portion of the package 15. Specifically, as shown in FIG. 4, when the positioning section 11a is arranged on the end part 15a of the package 15, the end surface of the guide member 11 is spaced from the surface of the sensor chip 17 by the gap Gp. With this configuration, the gap Gp having a predetermined width is secured between the guide member 11 and the sensor chip 17 by defining the position of the guide member 11. The gap Gp enables the material of the protection section 12 flows to the inside portion of the tubular section 11b so that the sensor chip 17, particularly the sensing portion 17a is sealed by the protection section 12.

(IV) In the present embodiment, the protection section 12 is made of gel material, which is gelatinized under the heating treatment. Since the material of the protection section 12 is gelatinized by heating treatment, the sealing of the components arranged in the package 15 can be performed with ease.

(V) In the present embodiment, as shown in FIG. 2, FIG. 4, and FIG. 6, the manufacturing method of the pressure sensing device 10 includes the position defining process and the sealing process. As shown in FIG. 2 and FIG. 4, in the position defining, process, the position of the guide member 11 is defined with respect to the package 15 so that the tubular section 11b of the guide member 11 is opposed to the sensing portion 17a and the end surface of the tubular section 11b of the guide member is spaced from the surface of the sensing portion 17a of the sensor chip 17 by the gap Gp. As shown in FIG. 6, in the sealing process, the material of the protection section 12 is filled into the package 15 from the outside portion of the tubular section 11b, and the fluid material of the protection section 12 flows to the inside portion of the tubular section 11b so that the sensor chip 17 and the bonding wires 13 are sealed by the protection section 12. With this method, the thickness of the protection section 12 sealed on the sensor chip 17 is smaller than the thickness of the protection section 12 sealed on other components and elements arranged in the package 15. Thus, the effect of the impact acceleration is reduced at the sensing portion 17a, and a false detection of the sensor chip 17 is substantially restricted. Further, the bonding wires 13 are entirely sealed by the protection section 12 so that the bonding wires 13 are not exposed to an outside. Thus, a fault caused by an exposure of the bonding wires 13 is restricted and a reliability of the pressure sensing device 10 is secured.

(VI) In the present embodiment, as shown in FIG. 5 and FIG. 7, the manufacturing method of the pressure sensing device 10 further includes the cap attaching process and the cap removing process. As shown in FIG. 5, in the cap attaching process, the cap 11e is air-tightly attached to the one end of the tubular section 11b. As shown in FIG. 7, in the cap removing process, the cap 11e is removed from the tubular section 11b after the sealing process. With this method, the material of the protection section 12 is filled into the package 15 under a condition that the cap 11e is air-tightly attached to the tubular section 11b. Thus, the thickness of the protection section 12 at the inside portion of the tubular section 11b can be set different from the thickness of the protection section 12 at the outside portion of the tubular section 11b. Specifically, the protection section 12 sealed on the sensor chip 17 can be formed thinner than the protection section 12 sealed on other components and elements arranged in the package 15.

### OTHER EMBODIMENTS

While only the selected exemplary embodiments have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiments according to the present disclosure is provided for illustration only, and not for the purpose of limiting the disclosure as defined by the appended claims and their equivalents. The following will describe other embodiments of the present disclosure.

In the foregoing embodiment, as shown in FIG. 6, the material of the protection section 12 is filled into the package 15 under a condition that the cap 11e is air-tightly attached to the one end of the tubular section 11b. Further, a member other than the cap 11e may be air-tightly attached to the tubular section 11b. Any member that is able to air-tightly seal the one end of the tubular section 11b and is able to bear an increase of the pressure at the inside portion of the tubular section 11b can be used instead of the cap 11e. Herein, the increase of the pressure at the inside portion of the tubular section 11b is caused by the movement of the material of the protection section 12 to the inside portion of the tubular section 11b. For example, an adhesive tape, clay, a rubber stopper, a plate-shaped member, or a flexible member can be used to air-tightly seal the one end of the tubular section 11b instead of the cap 11e. The protection section 12 sealed on the sensor chip 17 is formed thinner than the protection section 12 sealed on other components and elements with the above-described alternative members of the cap 11e. Thus, advantages similar to the advantages provided by the pressure sensing device 10 according to the foregoing embodiment are provided by this configuration. Further, the cap 11e and the above-described alternative members seal the one end of the tubular section 11b air-tightly in order to prevent an entering of outside air to the inside portion of the tubular section 11b and a leakage of the inside air to the outside portion of the tubular section 11b. Thus, the cap 11e and the above-described alternative members are also referred to as a sealing member.

In the foregoing embodiment, as shown in FIG. 3, the support section 11d includes the four sub sections that support the tubular section 11b. Further, the number of the sub sections of the support section 11d may be other than four. As shown in FIG. 3, the positioning section 11a and the support section 11d are formed so that a part of the opening of the package 15 is remained so that the material of the protection section 12 is provided through the remained opening of the package 15 to the inside portion of the package 15. The positioning section 11a and the support section 11d may have a different shape other than the example shown in FIG. 3 under a condition that the material of the protection section 12 can be provided through the remained opening of the package 15 to the inside portion of the package 15. Thus, advantages similar to the advantages provided by the pressure sensing device 10 according to the foregoing embodiment are provided by this configuration.

In the foregoing embodiment, as shown in FIG. 4, the guide member 11 is arranged so that the end surface of the tubular section 11b of the guide member 11 is spaced from the surface of the sensing portion 17a of the sensor chip 17 by the gap Gp. Further, the guide member 11 may be arranged so that the end surface of the tubular section 11b of the guide member 11 is contacted with the surface of the sensing portion 17a of the sensor chip 17 without the gap Gp. When the tubular section 11b is contacted with the sensing portion 17a, a notch, a through hole or a slit may be formed on the tubular section 11b so that the material of the protection section 12 flows to the inside portion of the tubular section 11b through the notch, the through hole or the slit. A configuration other than the notch, the through hole, the slit may be formed on the tubular section 11b under a condition that the material of the protection section 12 can flow to the inside portion of the tubular section 11b. With this configuration, since the one end of the tubular section 11b is air-tightly sealed by the cap 11e, the thickness of the protection section 12 at the inside portion of the tubular section 11b can be adjusted. Thus, with this configuration, advantages similar to the advantages provided by the pressure sensing device 10 according to the foregoing embodiment are provided.

What is claimed is:

1. A pressure sensing device comprising:
a sensor chip having a sensing portion, the sensor chip detecting a pressure with the sensing portion and generating a signal corresponding to the pressure detected by the sensing portion;
a bonding wire that is electrically connected with the sensor chip in order to transmit the signal generated by the sensor chip;
a protection section having an electrical insulation property and sealing the sensor chip and the bonding wire;
a package, in which the sensor chip, the bonding wire, and the protection section are arranged; and
a guide member having a tubular section arranged opposed to the sensing portion of the sensor chip,
wherein the protection section has a first thickness at an inside portion of the tubular section and has a second thickness at an outside portion of the tubular section, and the first thickness is smaller than the second thickness.

2. The pressure sensing device according to claim 1,
wherein the first thickness of the protection section at the inside portion of the tubular section is adjustable by changing a length of the tubular section.

3. The pressure sensing device according to claim 1,
wherein the guide member further includes a positioning section that defines a position of the guide member with respect to the package, and
wherein, when the position of the guide member is defined by the positioning section, an end surface of the guide member is spaced from a surface of the sensor chip by a gap.

4. The pressure sensing device according to claim 1,
wherein the protection section is made of gel material.

5. A manufacturing method of the pressure sensing device according to claim 1 comprising:
arranging the guide member having the tubular section so that the tubular section is opposed to the sensing portion and an end surface of the tubular section is spaced from a surface of the sensing portion by a gap; and
sealing the sensor chip and the bonding wire with the protection section by providing a material of the protection section from the outside portion of the tubular section.

6. The manufacturing method according to claim 5, further comprising:
attaching a cap at one end of the tubular section before the sealing of the sensor chip and the bonding wire; and
removing the cap from the tubular section after the sealing of the sensor chip and the bonding wire.
